(19) United States
(12) Patent Application Publication
(10) Pub. No.: US 2020/0091327 A1
(43) Pub. Date: Mar. 19, 2020

(54) INSULATED GATE BIPOLAR TRANSISTOR

(71) Applicant: TOYOTA JIDOSHA KABUSHIKI KAISHA, Toyota-shi (JP)

(72) Inventors: Hiroshi HOSOKAWA, Nagoya-shi (JP); Shinya IWASAKI, Toyota-shi (JP); Yuma KAGATA, Kariya-shi (JP)

(73) Assignee: TOYOTA JIDOSHA KABUSHIKI KAISHA, Toyota-shi (JP)

(21) Appl. No.: 16/536,451

(22) Filed: Aug. 9, 2019

(30) Foreign Application Priority Data
Sep. 18, 2018 (JP) 2018-174031

(51) Int. Cl. H01L 29/739; H01L 29/06; H01L 29/08; H01L 29/10; H01L 29/423

(52) U.S. Cl. CPC H01L 29/7397; H01L 29/0696; H01L 29/4236; H01L 29/1095; H01L 29/0804

(57) ABSTRACT

An insulated gate bipolar transistor may include a gate electrode provided in a rectangular trench. An emitter region is in direct contact with a straight trench constituting one side of the rectangular trench. A surface layer body region is in direct contact with the straight trench in a range adjacent to the emitter region. A body contact region is in direct contact with the emitter region from an opposite side to the straight trench. The body contact region includes a first part and a second part protruding toward the emitter region than the first part. A width of the emitter region between the second part and the straight trench is narrower than a width of the emitter region between the first part and the straight trench.

### TECHNICAL FIELD

The art disclosed herein relates to an insulated gate bipolar transistor.

### BACKGROUND

Japanese Patent Application Publication 2017-107948 (hereinafter JP 2017-107948 A) describes an insulated gate bipolar transistor (hereinbelow termed an IGBT (Insulated Gate Bipolar Transistor)). FIGS. 14 and 15 show the IGBT of JP 2017-107948 A. As shown in FIGS. 14 and 15, the IGBT of JP 2017-107948 A includes a rectangular trench. A gate insulating film 182 and a gate electrode 180 are provided in the rectangular trench. An upper surface of the gate electrode 180 is covered by an interlayer insulating film 178. The gate electrode 180 is insulated from an emitter electrode 150 by the interlayer insulating film 178. Emitter regions 122 of n-type, a body contact region 124 of high-concentration p-type, surface layer body regions 126 of p-type, a separation body region 127 of p-type, and a pillar region 128 of n-type are provided in a rectangular region 112 surrounded by the rectangular trench. The separation body region 127 is in direct contact with the emitter regions 122, the body contact region 124, and the surface layer body regions 126 from below, and is in direct contact with the rectangular trench. A drift region 134 of n-type is provided below the separation body region 127. Each of the emitter regions 122 is in direct contact with a straight trench 191 constituting one side of the rectangular trench. The surface layer body regions 126 are in direct contact with the straight trenches 191 in ranges adjacent to the respective emitter regions 122. The body contact region 124 is in direct contact with the emitter regions 122 from an opposite side to each of the straight trenches 191. When a potential that is at a gate threshold or greater is applied to the gate electrode 180, channels are generated in the surface layer body regions 126 and the separation body region 127. The emitter regions 122 and the drift region 134 are connected by the channels, by which electrons flow from the emitter regions 122 to the drift region 134. That is, the IGBT turns on. Since channels are formed not only in the separation body region 127 below the emitter regions 122 but also in the surface layer body regions 126 that are in direct contact with the emitter regions 122 in a lateral direction, thus this IGBT has a high channel density. Due to this, saturation current in this IGBT is high, thus a steady loss is less likely to occur in this IGBT.

### SUMMARY

When the IGBT turns on, not only the electrons but holes also flow. The holes flow from the drift region 134 to the emitter electrode 150 through the separation body region 127 and the body contact region 124. The holes having flowed into the separation body region 127 directly below the emitter regions 122 as shown by arrows 200 in FIG. 15 flow in the lateral direction below the emitter regions 122 as shown by arrows 202 in FIG. 15 and flow into the body contact region 124. In the IGBT of JP 2017-107948 A, since a width W122 of the emitter regions 122 is wide, a distance which the holes flow in the lateral direction below each of the emitter regions 122 is long, thus an electric resistance at such parts is high. As a result, a potential in the separation body region 127 directly below the emitter regions 122 tends to become high, and the holes can easily flow from the separation body region 127 to the emitter regions 122. Due to this, there is a problem that latch up easily occurs.

The latch up can be suppressed by narrowing the width W122 of the emitter regions so that passages of the holes shown by the arrows 202 are shortened. However, since a part of a surface of each of the emitter regions 122 is covered by the interlayer insulating film 178, a contact area of each emitter region 122 to the emitter electrode 150 is small. When the width W122 of the emitter regions 122 is narrowed than the width shown in FIG. 15, the contact areas of the emitter regions 122 to the emitter electrode 150 become extremely small, and a contact resistance thereof becomes extremely high.

Thus, the description herein proposes an art that suppresses latch up while suppressing an increase in a contact resistance in an IGBT including a rectangular trench.

An insulated gate bipolar transistor disclosed herein may comprise: a semiconductor substrate; an emitter electrode provided on an upper surface of the semiconductor substrate; a collector electrode provided on a lower surface of the semiconductor substrate; a rectangular trench provided in the upper surface and extending in a rectangular shape at the upper surface; a gate insulating film provided in the rectangular trench; a gate electrode provided in the rectangular trench, extending in a rectangular shape along the rectangular trench, and insulated from the semiconductor substrate by the gate insulating film; and an interlayer insulating film insulating the gate electrode from the emitter electrode, wherein the semiconductor substrate comprises: an emitter region of n-type provided in a rectangular region surrounded by the rectangular trench and being in direct contact with the emitter electrode; a body contact region of p-type provided in the rectangular region and being in direct contact with the emitter electrode; a surface layer body region of p-type provided in the rectangular region, being in direct contact with the emitter electrode, and having a p-type impurity concentration lower than that of the body contact region; a separation body region of p-type being in direct contact with the emitter region, the body contact region, and the surface layer body region from below, being in direct contact with the rectangular trench, and having a p-type impurity concentration lower than that of the body contact region; a drift region of n-type provided below the separation body region, separated from the emitter region by the separation body region, and being in direct contact with a lower end of the rectangular trench; and a collector region of p-type provided below the drift region, separated from the separation body region by the drift region, and being in direct contact with the collector electrode, the rectangular trench comprises a straight trench which constitutes one side of the rectangular trench, the emitter region is in direct contact with the straight trench, the surface layer body region is in direct contact with the straight trench in a range adjacent to the emitter region, the body contact region is in direct contact with the emitter region from an opposite side to the straight trench, the body contact region comprises a first part and a second part protruding toward the emitter region than the first part, and a width of the emitter region between the second part and the straight trench is narrower than a width of the emitter region between the first part and the straight trench.

In this IGBT, the body contact region comprises the second part protruding toward the emitter region than the first part, and the width of the emitter region between the second part and the straight trench is narrow. Due to this, holes that have flowed into the separation body region directly below the emitter region easily flow into the second part of the body contact region. Due to this, a passage in which the holes flow within the separation body region is short, and a potential in the separation body region directly below the emitter region is less likely to increase. Thus, the holes do not easily flow into the emitter region and latch up is less likely to occur. Further, since the width of the emitter region between the first part and the straight trench is wide, a contact area between the emitter region and the emitter electrode can be ensured at this portion. An increase in a contact resistance can thereby be suppressed. As such, according to this IGBT, the latch up can be suppressed while suppressing the increase in the contact resistance.

### BRIEF DESCRIPTION OF DRAWINGS

FIG. 1 is a plan view showing an upper surface of a semiconductor substrate;

FIG. 2 is a vertical cross-sectional view along a line II-II in FIG. 1;

FIG. 3 is a vertical cross-sectional view along a line III-III in FIG. 1;

FIG. 4 is a vertical cross-sectional view along a line IV-IV in FIG. 1;

FIG. 5 is a vertical cross-sectional view along a line V-V in FIG. 1;

FIG. 6 is an enlarged plan view of a rectangular region;

FIG. 7 is an enlarged plan view of an emitter region and its periphery;

FIG. 8 is an enlarged cross-sectional view of the emitter region of FIG. 2 and its periphery;

FIG. 9 is an enlarged cross-sectional view of the emitter region of FIG. 3 and its periphery;

FIG. 10 is an enlarged plan view of the emitter region and its periphery;

FIG. 11 is an enlarged plan view of an IGBT of a first variant corresponding to FIG. 6;

FIG. 12 is a vertical cross-sectional view of an IGBT of the first variant corresponding to FIG. 2;

FIG. 13 is an enlarged plan view of an IGBT of a second variant corresponding to FIG. 7;

FIG. 14 is an enlarged plan view of a semiconductor device of JP 2017-107948 A; and

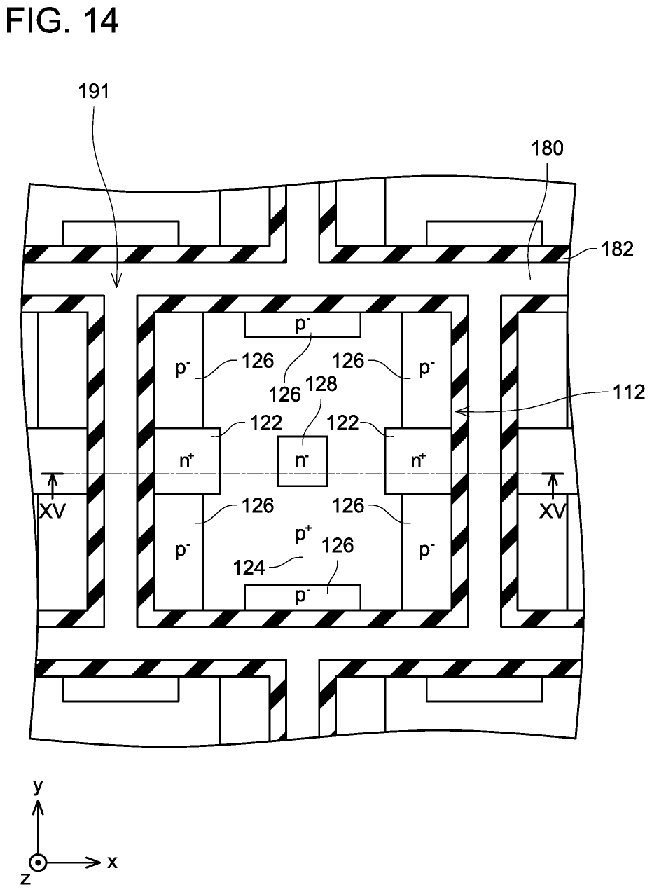

FIG. 15 is a vertical cross-sectional view of the semiconductor device of JP 2017-107948 A.

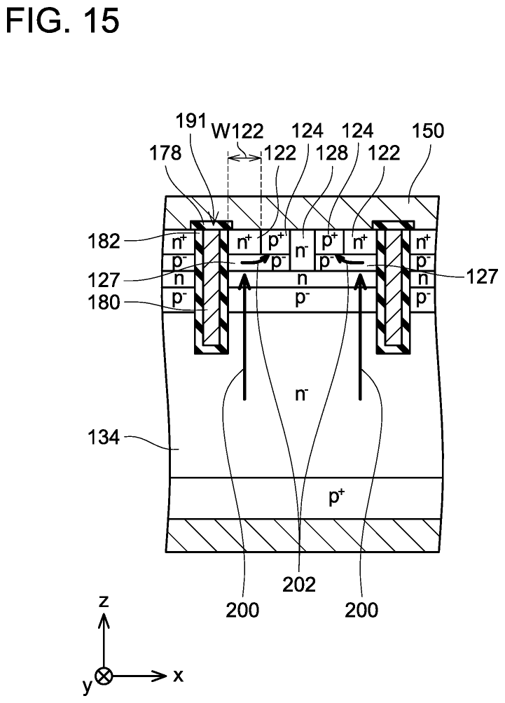

### DETAILED DESCRIPTION

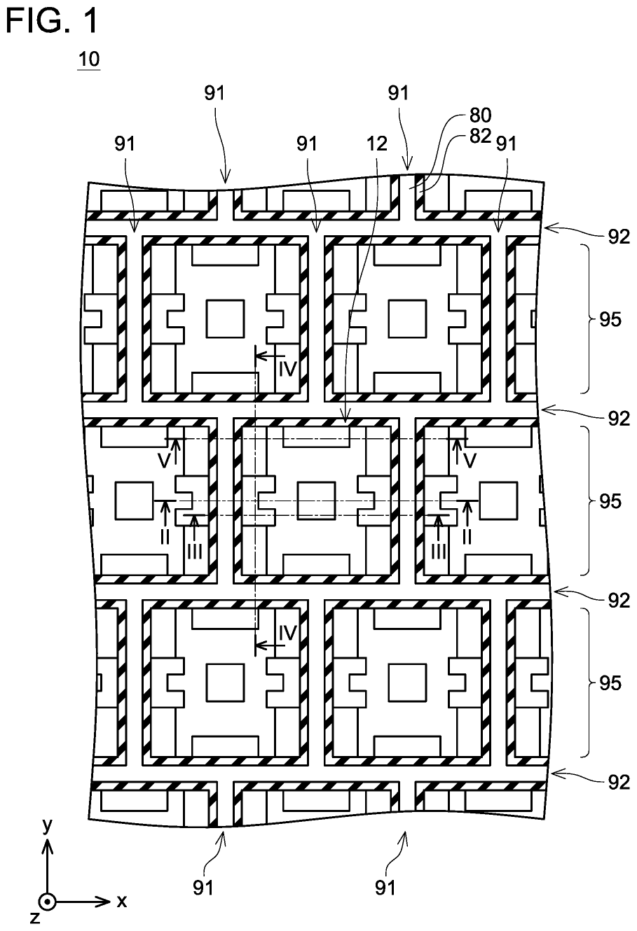

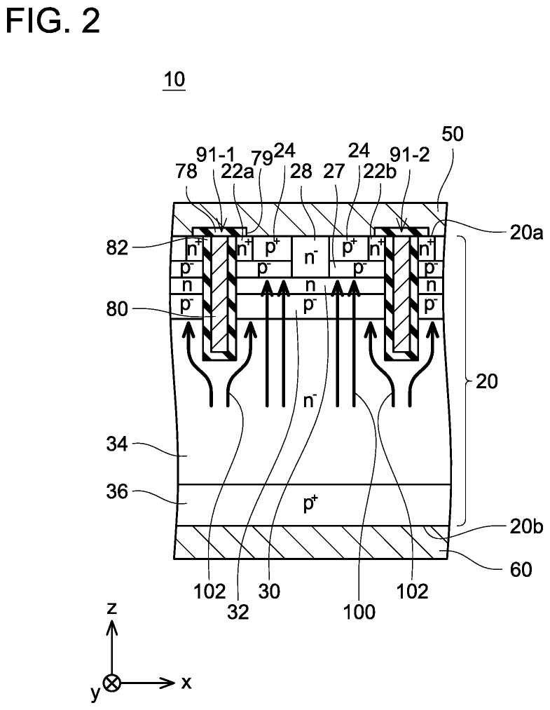

FIGS. 1 to 5 show an IGBT 10 of an embodiment. As shown in FIGS. 2 to 5, the IGBT 10 comprises a semiconductor substrate 20, an emitter electrode 50, and a collector electrode 60. The emitter electrode 50 is provided at an upper surface 20a of the semiconductor substrate 20. The collector electrode 60 is provided at a lower surface 20b of the semiconductor substrate 20. In FIG. 1, a structure above the upper surface 20a of the semiconductor substrate 20 such as the emitter electrode 50 is omitted. Further, in the description below, one direction parallel to the upper surface 20a is termed an x direction, a direction parallel to the upper surface 20a and perpendicular to the x direction is termed a y direction, and a thickness direction of the semiconductor substrate 20 (that is, a direction perpendicular to the x and y directions) is termed a z direction.

As shown in FIG. 1, a plurality of trenches 91 and a plurality of trenches 92 are provided in the upper surface 20a of the semiconductor substrate 20. As shown in FIGS. 2 to 5, each of the trenches 91, 92 extends substantially vertical to the upper surface 20a of the semiconductor substrate 20 (that is, in the z direction). As shown in FIG. 1, each of the trenches 92 extends in the x direction in a straight line shape when seeing the upper surface 20a of the semiconductor substrate 20 in plan view. The plurality of trenches 92 are arranged along the y direction with intervals therebetween. Each of the trenches 91 extends in the y direction in a straight line shape when seeing the upper surface 20a of the semiconductor substrate 20 in plan view. The trenches 91 are provided in plurality in each of regions 95 interposed between two trenches 92. Respective ends of each trench 91 are connected to the trenches 92 located on its respective sides. Each trench 91 is arranged to be offset along the x direction with respect to other trenches 91 that are adjacent thereto in the y direction. Each trench 91 intersects with each of its corresponding trenches 92 in a three-way junction shape at each end of the trench 91. The upper surface 20a of the semiconductor substrate 20 is partitioned into rectangular regions by the trenches 91 and 92. Hereinbelow, the rectangular semiconductor regions partitioned by the trenches 91, 92 will be termed rectangular regions 12. Further, hereinbelow, a set of the trenches 91, 92 surrounding one rectangular region 12 will be termed a rectangular trench.

As shown in FIGS. 1 to 5, an inner surface of the rectangular trench (that is, a bottom and side surfaces) is covered by a gate insulating film 82. A gate electrode 80 is provided inside the rectangular trench. The gate electrode 80 opposes the semiconductor substrate 20 via the gate insulating film 82. The gate electrode 80 is insulated from the semiconductor substrate 20 by the gate insulating film 82. The gate electrode 80 is provided by traversing over insides of the trenches 91 and insides of the trenches 92. As such, the gate electrode 80 extends in a rectangular shape along the rectangular trench. Due to this, when seen from above in plan view as in FIG. 1, a periphery of each rectangular region 12 is surrounded by the gate electrode 80. Further, as shown in FIGS. 2 to 5, an upper surface of the gate electrode 80 is covered by an interlayer insulating film 78. The upper surface 20a of the semiconductor substrate 20 in vicinities of the trenches 91, 92 is also covered by the interlayer insulating film 78. The emitter electrode 50 is provided to cover the interlayer insulating film 78. The gate electrode 80 is insulated from the emitter electrode 50 by the interlayer insulating film 78. The emitter electrode 50 is in direct contact with the upper surface 20a of the semiconductor substrate 20 within each of openings 79 where the interlayer insulating film 78 is not provided.

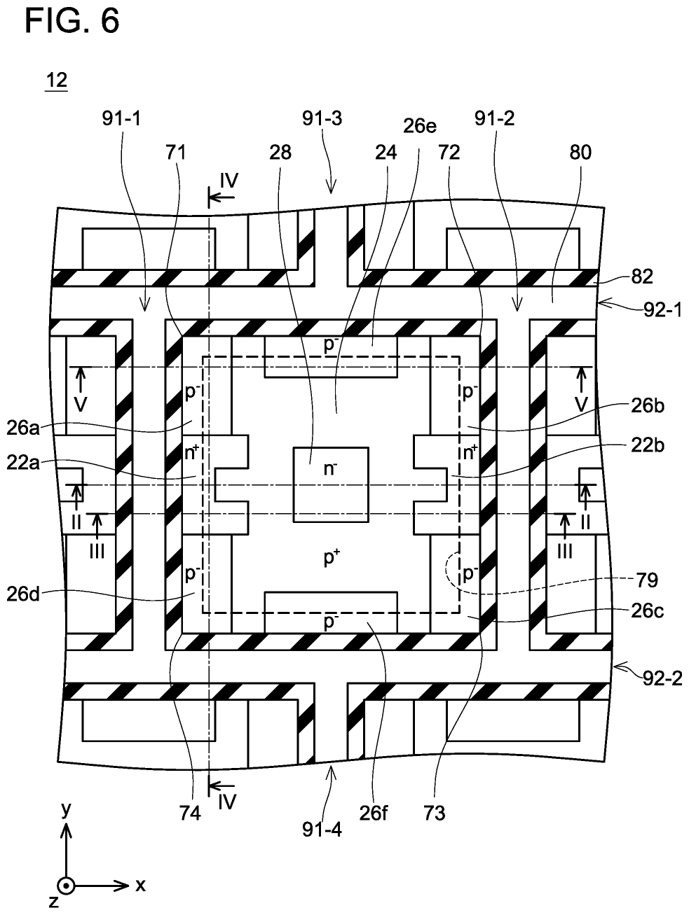

Next, a structure of each rectangular region 12 will be described. Since all the rectangular regions 12 have a structure that is same as one another, the structure of one rectangular region 12 will be described hereinbelow. FIG. 6 is an enlarged plan view of one rectangular region 12. As shown in FIG. 6, the rectangular trench is constituted of two trenches 91 (trenches 91-1 and 91-2) and two trenches 92 (trenches 92-1 and 92-2). In other words, the rectangular region 12 is surrounded by the trenches 91-1, 91-2, 92-1, and 92-2. Hereinbelow, within the rectangular region 12, a portion adjacent to a junction between the trenches 91-1 and 92-1 will be termed a corner 71, a portion adjacent to a junction between the trenches 92-1 and 91-2 will be termed a corner 72, a portion adjacent to a junction between the trenches 91-2 and 92-2 will be termed a corner 73, and a portion adjacent to a junction between the trenches 92-2 and 91-1 will be termed a corner 74. Further, a trench 91-3 constituting an adjacent rectangular trench is connected to the trench 92-1. Further, a trench 91-4 constituting another adjacent rectangular trench is connected to the trench 92-2. Further, FIG. 6 shows a position of the opening 79 by a broken line. As shown in FIG. 6, the opening 79 is provided within the rectangular region 12. Inside the opening 79, the emitter electrode 50 is in direct contact with the upper surface 20a of the semiconductor substrate 20.

As shown in FIGS. 2 to 6, emitter regions 22, a body contact region 24, surface layer body regions 26, a separation body region 27, a pillar region 28, a barrier region 30, and a lower body region 32 are provided inside each rectangular region 12.

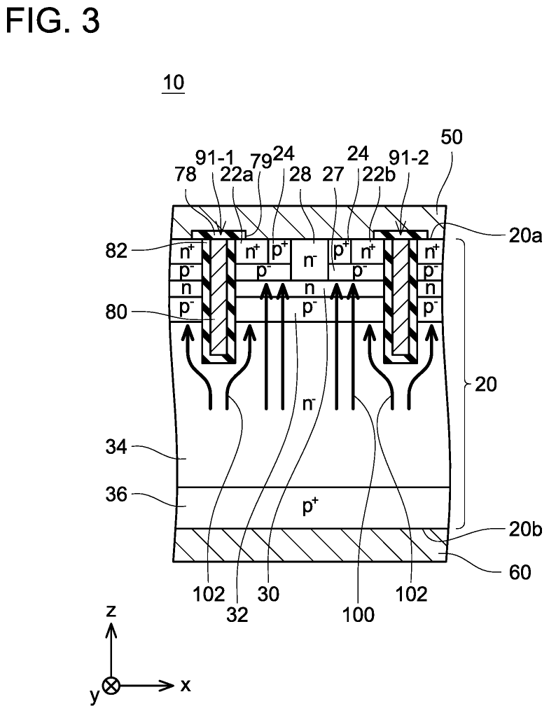

The pillar region 28 is constituted of a n-type semiconductor having a low n-type impurity concentration. As shown in FIGS. 2 and 3, the pillar region 28 is provided in a range exposed at the upper surface 20a of the semiconductor substrate 20. As shown in FIGS. 2, 3, and 6, the pillar region 28 is in Schottky contact with the emitter electrode 50 within the opening 79. The pillar region 28 is provided at a center of the rectangular region 12.

The body contact region 24 is constituted of a p-type semiconductor having a high p-type impurity concentration. As shown in FIGS. 2, 3, and 5, the body contact region 24 is provided in the range exposed at the upper surface 20a of the semiconductor substrate 20. As shown in FIG. 6, the body contact region 24 surrounds a periphery of the pillar region 28 at the upper surface 20a. As shown in FIGS. 2, 3, 5, and 6, the body contact region 24 is in ohmic contact with the emitter electrode 50 in the opening 79. The body contact region 24 is in direct contact with the gate insulating film 82 in the trenches 92-1, 92-2. Hereinbelow, being in direct contact with a gate insulating film in a trench may be termed “being in direct contact with the trench”. The body contact region 24 is in direct contact with the trenches 92-1 and 92-2 but is not is in direct contact with the trenches 91-1 and 91-2.

The emitter regions 22 are constituted of an n-type semiconductor having a high n-type impurity concentration. As shown in FIG. 6, two emitter regions 22a, 22b are provided in one rectangular region 12. As shown in FIGS. 2, 3, and 4, each of the emitter regions 22 is provided in the range exposed at the upper surface 20a of the semiconductor substrate 20. As shown in FIG. 6, a part of each emitter region 22 is provided in the opening 79, and other parts of each emitter region 22 are provided outside the opening 79 (that is, in a range covered by the interlayer insulating film 78). As shown in FIGS. 2, 3, 4, and 6, each emitter region 22 is in ohmic contact with the emitter electrode 50 in the opening 79. As shown in FIG. 6, one emitter region 22a is in direct contact with the trench 91-1. The emitter region 22a is in direct contact with the trench 91-1 at a center position of one side of the rectangular region 12. The other emitter region 22b is in direct contact with the trench 91-2. The emitter region 22b is in direct contact with the trench 91-2 at a center position of another side of the rectangular region 12.

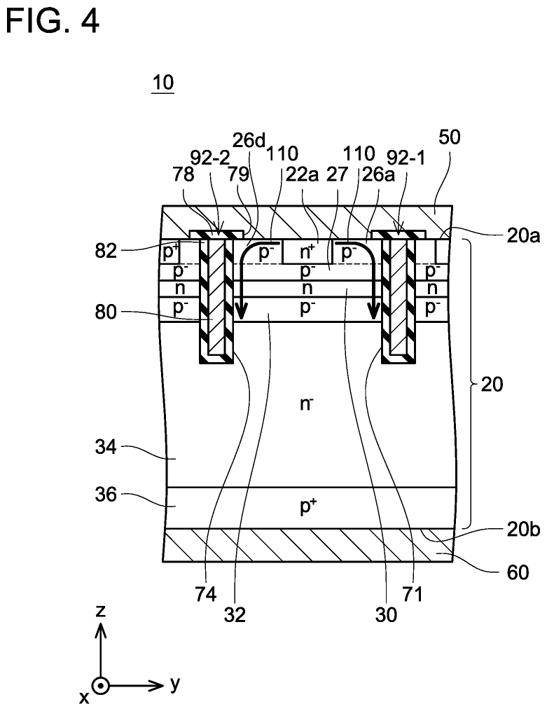

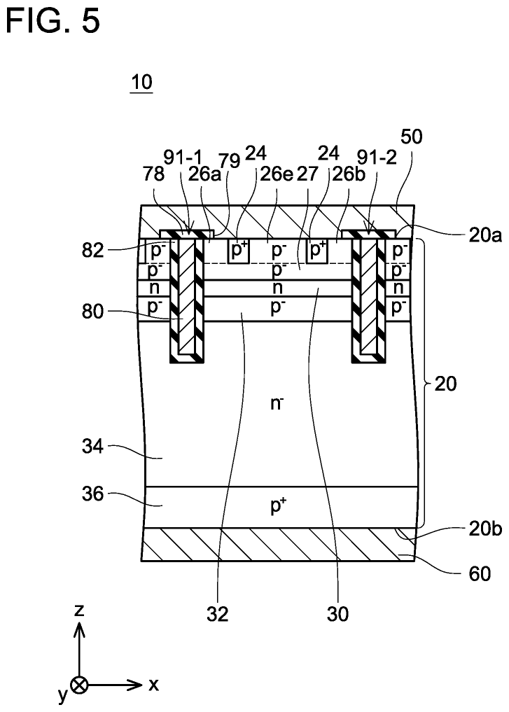

The surface layer body regions 26 are constituted of a semiconductor having a p-type impurity concentration lower than that of the body contact region 24. As shown in FIGS. 4 and 5, the surface layer body regions 26 are provided in the range exposed at the upper surface 20a of the semiconductor substrate 20. As shown in FIG. 6, the surface layer body regions 26 are separated into six regions 26a to 26f by the body contact region 24. The surface layer body region 26a is in direct contact with the trenches 91-1 and 92-1 at the corner 71. The surface layer body region 26a is in direct contact with the trench 91-1 over an entire range thereof from the corner 71 to the emitter region 22a. The surface layer body region 26b is in direct contact with the trenches 91-2 and 92-1 at the corner 72. The surface layer body region 26b is in direct contact with the trench 91-2 over an entire range thereof from the corner 72 to the emitter region 22b. The surface layer body region 26c is in direct contact with the trenches 91-2 and 92-2 at the corner 73. The surface layer body region 26c is in direct contact with the trench 91-2 over an entire range thereof from the corner 73 to the emitter region 22b. The surface layer body region 26d is in direct contact with the trenches 91-1 and 92-2 at the corner 74. The surface layer body region 26d is in direct contact with the trench 91-1 over an entire range thereof from the corner 74 to the emitter region 22a. The surface layer body region 26e is in direct contact with the trench 92-1. The body contact region 24 is in direct contact with the trench 92-1 on both sides of the surface layer body region 26e. The surface layer body region 26f is in direct contact with the trench 92-2. The body contact region 24 is in direct contact with the trench 92-2 on both sides of the surface layer body region 26f. The surface layer body regions 26a to 26f are in direct contact with the emitter electrode 50 in the opening 79.

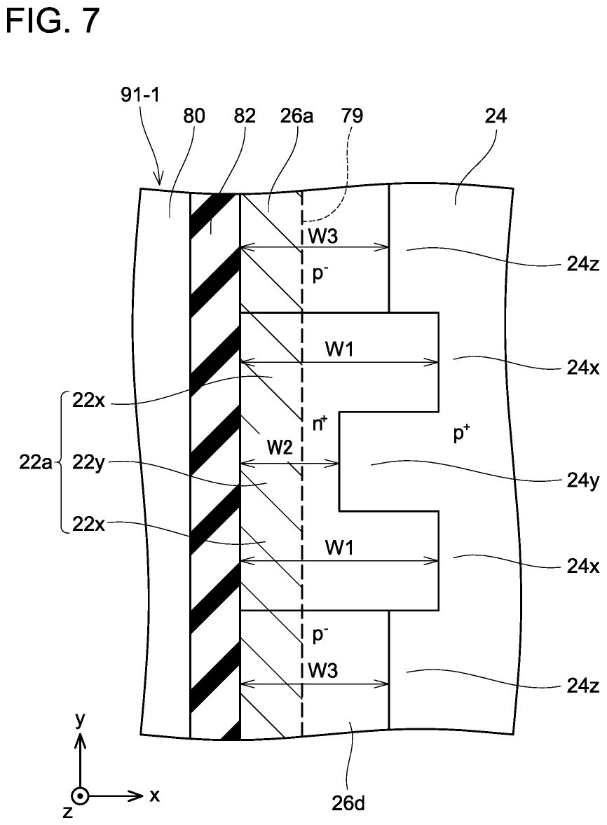

As shown in FIG. 6, the body contact region 24 is in direct contact with the emitter region 22a from an opposite side to the trench 91-1. FIG. 7 shows an enlarged view of the emitter region 22a and its periphery. As shown in FIG. 7, the body contact region 24 in a range in direct contact with the emitter region 22a includes first parts 24x and a second part 24y that protrudes toward the emitter region 22a than the first parts 24x. As such, the emitter region 22a between each of the first parts 24x and the trench 91-1 is configured as a wide-width part 22x having a wide width W1, and the emitter region 22a between the second part 24y and the trench 91-1 is configured as a narrow-width part 22y having a narrow width W2. Further, the body contact region 24 is in direct contact with the surface layer body regions 26a, 26d from the opposite side to the trench 91-1. Hereinbelow, parts of the body contact region 24 being in direct contact with the surface layer body regions 26a, 26d will be termed third parts 24z. The surface layer body regions 26a, 26d between each of the third parts 24z and the trench 91-1 have a width W3. As shown in FIG. 7, the width W3 is wider than the width W2 and narrower than the width W1 (that is, W1>W3>W2). Further, in FIG. 7, a semiconductor layer located outside the opening 79 (that is, the semiconductor layer covered by the interlayer insulating film 78) is indicated with oblique hatching. As shown in FIG. 7, the semiconductor layer in vicinity of the rectangular trench is located outside the opening 79 and is covered by the interlayer insulating film 78. Since the width W2 of the narrow-width part 22y is narrow, a majority of the narrow-width part 22y is covered by the interlayer insulating film 78. On the other hand, since the width W1 of the wide-width parts 22x is wide, a majority of each of the wide-width parts 22x is located in the opening 79, by which the wide-width parts 22x are in ohmic contact with the emitter electrode 50 by large areas. Due to this, a contact resistance of the emitter region 22a with respect to the emitter electrode 50 is reduced. The emitter region 22b is constituted substantially similar to FIG. 7, thus is in contact with the emitter electrode 50 by large areas at the wide-width parts 22x.

The separation body region 27 is constituted of a p-type semiconductor having a p-type impurity concentration lower than that of the body contact region 24. The p-type impurity concentrations of the surface layer body regions 26 and the separation body region 27 are substantially same. As shown in FIGS. 2 to 5, the separation body region 27 is provided below the emitter regions 22, the body contact region 24, and the surface layer body regions 26. The separation body region 27 is in direct contact with the emitter regions 22, the body contact region 24, and the surface layer body regions 26 from below. The separation body region 27 spreads over an entire range of the rectangular region 12 in a lateral direction (x and y directions) except underneath the pillar region 28. The pillar region 28 extends downward from the upper surface 20a and penetrates the separation body region 27. The separation body region 27 is in direct contact with the trenches 91-1, 91-2, 92-1 and 92-2 below the emitter regions 22, the body contact region 24, and the surface layer body regions 26.

The barrier region 30 is constituted of a n-type semiconductor having an n-type impurity concentration lower than that of the emitter regions 22. As shown in FIGS. 2 to 5, the barrier region 30 is provided below the separation body region 27 and the pillar region 28. The barrier region 30 is in direct contact with the separation body region 27 and the pillar region 28 from below. The barrier region 30 spreads over the entire range of the rectangular region 12 in the lateral direction (x and y directions). The barrier region 30 is in direct contact with the trenches 91-1, 91-2, 92-1 and 92-2 below the separation body region 27. The barrier region 30 is separated from the emitter regions 22 by the separation body region 27.

The lower body region 32 is constituted of a p-type semiconductor having a p-type impurity concentration lower than that of the body contact region 24. As shown in FIGS. 2 to 5, the lower body region 32 is provided below the barrier region 30. The lower body region 32 is in direct contact with the barrier region 30 from below. The lower body region 32 spreads over the entire range of the rectangular region 12 in the lateral direction (x and y directions). The lower body region 32 is in direct contact with the trenches 91-1, 91-2, 92-1 and 92-2 below the barrier region 30. The lower body region 32 is separated from the separation body region 27 by the barrier region 30.

The semiconductor substrate 20 includes a drift region 34 and a collector region 36. The drift region 34 and the collector region 36 are provided below the plurality of rectangular regions 12.

The drift region 34 is constituted of an n-type semiconductor having a n-type impurity concentration lower than those of the barrier region 30 and the pillar region 28. As shown in FIGS. 2 to 5, the drift region 34 is provided below the lower body region 32. The drift region 34 is in direct contact with the lower body region 32 from below. The drift region 34 spreads in the lateral direction over a range below the plurality of rectangular regions 12. The drift region 34 spreads over an entire range in the lateral direction (x and y directions) of the semiconductor substrate 20. The drift region 34 is in direct contact with lower ends of the respective trenches 91, 92. The drift region 34 is separated from the barrier region 30 by the lower body region 32.

The collector region 36 is constituted of a p-type semiconductor having a p-type impurity concentration higher than those of the separation body region 27 and the lower body region 32. As shown in FIGS. 2 to 5, the collector region 36 is provided below the drift region 34. The collector region 36 is in direct contact with the drift region 34 from below. The collector region 36 is separated from the lower body region 32 by the drift region 34. The collector region 36 is provided in a range exposed at the lower surface 20b of the semiconductor substrate 20. The collector region 36 is in ohmic contact with the collector electrode 60.

Next, an operation of the IGBT 10 will be described. Upon using the IGBT 10, a voltage which sets the collector electrode 60 as a positive side is applied between the collector electrode 60 and the emitter electrode 50. When a voltage that is at a gate threshold or greater is applied to the gate electrode 80, the surface layer body regions 26, the separation body region 27, and the lower body region 32 in ranges thereof in direct contact with the gate insulating film 82 invert to an n type, by which channels are formed. For example, in the cross sections shown in FIGS. 2 and 3, the channels are formed in the separation body region 27 and the lower body region 32 in the ranges thereof in direct contact with the gate insulating film 82 in the trenches 91. When the channels are formed, electrons flow into the drift region 34 from the emitter electrode 50 through the emitter regions 22 and the channels. Simultaneously therewith, holes flow into the drift region 34 from the collector electrode 60 through the collector region 36. As a result, an electric resistance of the drift region 34 decreases due to a conductivity modulation phenomenon. The electrons that had flowed into the drift region 34 travel through the drift region 34 and the collector region 36 and flow to the collector electrode 60. As above, current flows in the IGBT 10 by the electrons flowing from the emitter electrode 50 to the collector electrode 60.

Further, the holes that had flowed into the drift region 34 travel through the lower body region 32 and the barrier region 30 and flow to the separation body region 27 as shown by arrows 100 in FIGS. 2 and 3, and thereafter flow from the body contact region 24 to the emitter electrode 50. At this occasion, the barrier region 30 serves as a barrier that interrupts flow of the holes. As such, the holes are suppressed from flowing to the separation body region 27. As a result, a hole concentration in the drift region 34 increases, by which the electric resistance of the drift region 34 is further reduced. Due to this, an on-voltage of the IGBT 10 is reduced.

Further, as shown by arrows 102 in FIGS. 2 and 3, the holes in the drift region 34 below the trenches 91 flow while avoiding the trenches 91. Similarly, the holes in the drift region 34 below the trenches 92 flow while avoiding the trenches 92. Due to this, the holes flowing while avoiding the trenches 91 and the holes flowing while avoiding the trenches 92 concentrate in the drift region 34 located at the corners 71 to 74 of the rectangular region 12, by which the hole concentration thereof becomes extremely high. Due to this, at the corners 71 to 74, the electric resistance of the drift region 34 becomes extremely low. As shown in FIGS. 4 and 6, since the surface layer body regions 26 are in direct contact with the trenches 91 over entire ranges between the emitter regions 22 and the corners 71 to 74, the channels are formed over the entire ranges from the emitter regions 22 to the corners 71 to 74. As such, as shown by arrows 110 in FIG. 4, the electrons can flow from the emitter regions 22 to the drift region 34 at the corners 71 to 74. Thus, the electrons can flow by traveling through regions with the extremely low electric resistance. Due to this, the on-voltage of the IGBT 10 is further reduced.

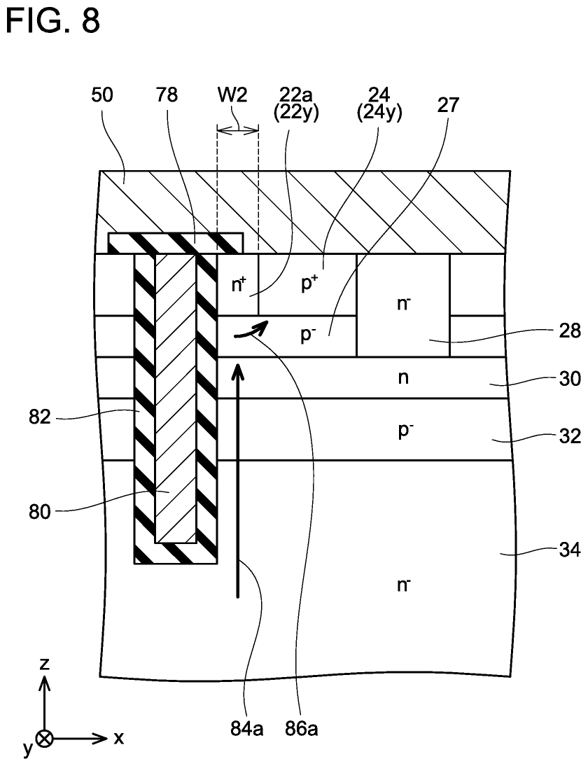

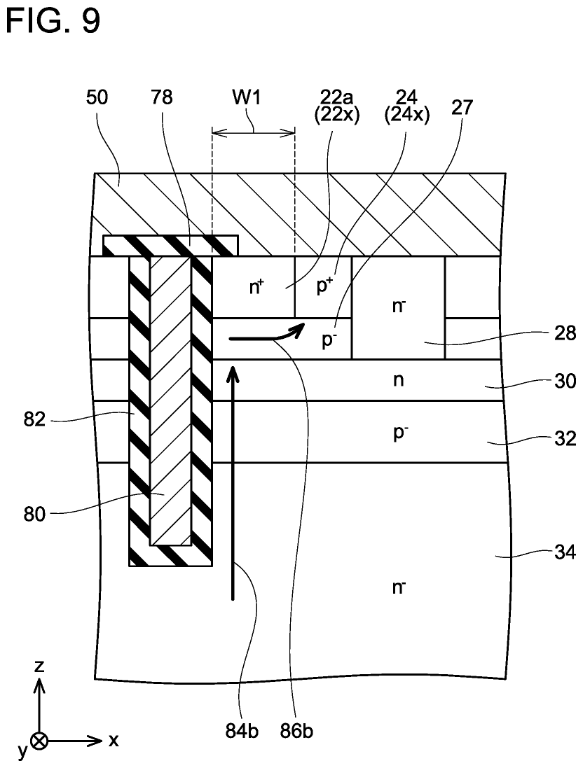

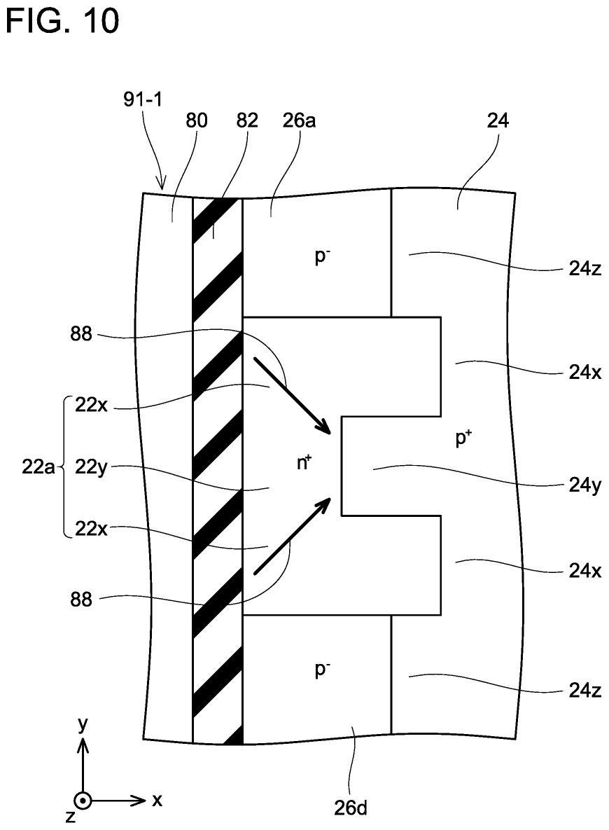

FIG. 8 shows an enlarged view in vicinity of the emitter region 22a of FIG. 2. Further, FIG. 9 shows an enlarged view in vicinity of the emitter region 22a of FIG. 3. Since the operation of the IGBT 10 is same on an emitter region 22a side and on an emitter region 22b side, thus the operation on the emitter region 22a side will primarily be described hereinbelow. As shown in FIGS. 8 and 9, the holes flow as shown by arrows 84a, 84b into the separation body region 27 directly below the emitter region 22a. The holes that had flowed into the separation body region 27 flow to the body contact region 24. As shown in FIG. 8, since the width W2 of the narrow-width part 22y is narrow, a passage from the separation body region 27 directly below the narrow-width part 22y to the second part 24y of the body contact region 24 (that is, a passage shown by an arrow 86a) is short, and an electric resistance of this passage is low. As such, a majority of the holes having flowed into the separation body region 27 directly below the narrow-width part 22y flows to the second part 24y as shown by the arrow 86a. On the other hand, as shown in FIG. 9, since the width W1 of the wide-width parts 22x is wide, passages from the separation body region 27 directly below the wide-width parts 22x to the first parts 24x of the body contact region 24 (that is, passages shown by an arrow 86b) are long, and an electric resistance of these passages is high. Thus, the holes that had flowed into the separation body region 27 directly below the wide-width parts 22x do not flow easily in the passages of the arrow 86b. As shown by arrows 88 in FIG. 10, a majority of the holes having flowed into the separation body region 27 directly below the wide-width parts 22x flow within the separation body region 27 obliquely toward the second part 24y. As above, since the body contact region 24 includes the second part 24y protruding toward the emitter region 22a, the holes having flowed into the separation body region 27 directly below the emitter region 22a can flow to the second part 24y through the passages with a low electric resistance. As above, since a large quantity of holes flow to the second part 24y through the passages with the low electric resistance, a potential in the separation body region 27 directly below the emitter region 22a is less likely to become high. Due to this, the holes are less likely to flow from the separation body region 27 to the emitter region 22a, and latch up is less likely to occur in the IGBT 10.

Further, as aforementioned, in the IGBT 10 of the embodiment has the emitter region 22a in direct contact with the emitter electrode 150 over wide areas at the wide-width parts 22x, a contact resistance of the emitter region 22a to the emitter electrode 150 is low. As such, according to the IGBT 10 of the embodiment, the latch up can be suppressed while maintaining the contact resistance of the emitter regions 22 to the emitter electrode 150 low.

Further, as shown in FIG. 7, in the IGBT 10, the width W3 of the surface layer body regions 26 between the third parts 24z of the body contact region 24 and the trench 91-1 is wider than the width W2 of the emitter region 22a between the second part 24y of the body contact region 24 and the trench 91-1. That is, an interval between the body contact region 24 and channel portions (boundaries between the surface layer body regions 26 and the gate insulating film 82) is large. Due to this, the channel portions of the surface layer body regions 26 are less likely to be affected by p-type impurities in the body contact region 24, and channels can easily be formed in the surface layer body regions 26. Due to this, a resistance in the channels formed in the surface layer body regions 26 is thereby small. Thus, a steady loss is less likely to occur in the IGBT 10.

Further, in the IGBT 10, the body contact region 24 is not in direct contact with the trenches 91-1, 91-2, thus the surface layer body regions 26 can be provided widely over ranges in direct contact with the trenches 91-1, 91-2. According to this configuration, the electrons are more likely to flow to the corners 71 to 74. Due to this, the steady loss can further be reduced.

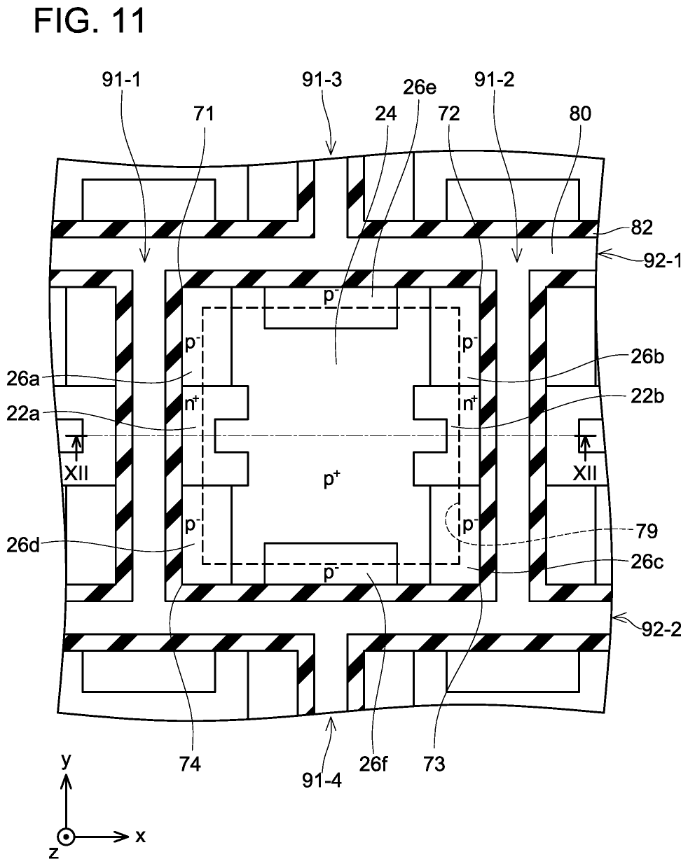

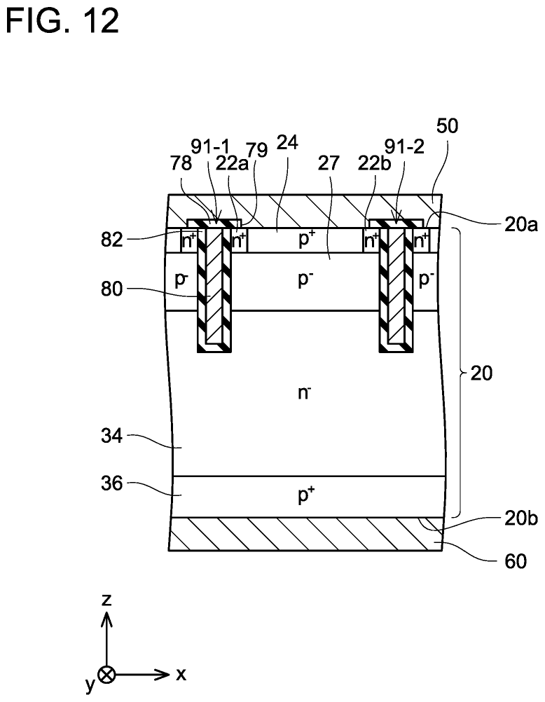

In the aforementioned embodiment, the IGBT 10 includes the barrier region 30 and the pillar region 28, however, as shown in FIGS. 11 and 12, the IGBT may not include the barrier region 30 and the pillar region 28. In this case, the separation body region 27 is in direct contact with the drift region 34. The IGBT can operate with such a configuration as well. Further, a configuration in which the barrier region 30 is provided but the pillar region 28 is not provided may be employed.

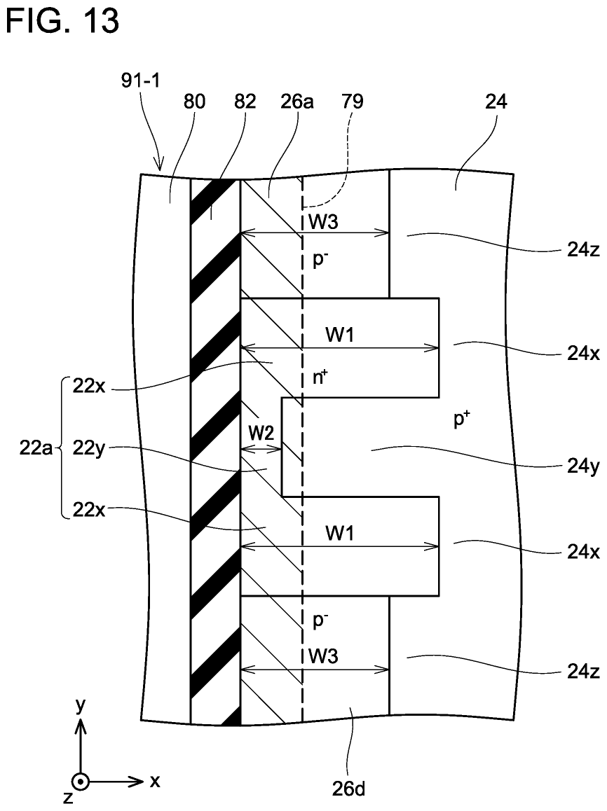

Further, in the aforementioned embodiment, a part of the narrow-width part 22y in the emitter region 22a is provided in the opening 79. However, as shown in FIG. 13, the second part 24y of the body contact region 24 may extend to outside the opening 79, and an entirety of the narrow-width part 22y may be provided outside the opening 79 (that is, in the range covered by the interlayer insulating film 78). With such a configuration as well, the emitter region 22a can be brought into direct contact with the emitter electrode 50 at the wide-width parts 22x, thus no problem would particularly arise.

A relationship between the respective constituent elements of the aforementioned embodiment and the constituent elements of the claims will be described below. The trench 91-1 of the embodiment is an example of a straight trench in the claims. The width W1 of the embodiment is an example of “a width of the emitter region between the first part and the straight trench” in the claims. The width W2 of the embodiment is an example of “a width of the emitter region between the second part and the straight trench” in the claims. The width W3 of the embodiment is an example of “a width of the surface layer body region between the third part and the straight trench” in the claims.

Some of the features characteristic to below-described embodiments will herein be listed. It should be noted that the respective technical elements are independent of one another, and are useful solely or in combinations.

In an example of an IGBT disclosed herein, the body contact region may comprise a third part being in direct contact with the surface layer body region from an opposite side to the straight trench. A width of the surface layer body region between the third part and the straight trench may be wider than the width of the emitter region between the second part and the straight trench.

When a body contact region with a high p-type impurity concentration is present in vicinity of a channel portion in the separation body region (region in direct contact with the straight trench), a hole concentration in the channel portion becomes high due to an influence from the body contact region. Due to this, a resistance of a channel thereof becomes high. Contrary to this, by widening the width of the surface layer body region between the third part and the straight trench, the influence from the body contact region on the channel portion is suppressed, and an increase in the channel resistance can be suppressed.

In an example of an IGBT disclosed herein, the body contact region may not be in direct contact with the straight trench.

According to this configuration, the channel portion (that is, a portion where the surface layer body region and the straight trench are in direct contact) can be provided widely.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. An insulated gate bipolar transistor, comprising:
a semiconductor substrate;
an emitter electrode provided on an upper surface of the semiconductor substrate;
a collector electrode provided on a lower surface of the semiconductor substrate;
a rectangular trench provided in the upper surface and extending in a rectangular shape at the upper surface;
a gate insulating film provided in the rectangular trench;
a gate electrode provided in the rectangular trench, extending in a rectangular shape along the rectangular trench, and insulated from the semiconductor substrate by the gate insulating film; and
an interlayer insulating film insulating the gate electrode from the emitter electrode,
wherein
the semiconductor substrate comprises:
an emitter region of n-type provided in a rectangular region surrounded by the rectangular trench and being in direct contact with the emitter electrode;
a body contact region of p-type provided in the rectangular region and being in direct contact with the emitter electrode;
a surface layer body region of p-type provided in the rectangular region, being in direct contact with the emitter electrode, and having a p-type impurity concentration lower than that of the body contact region;
a separation body region of p-type being in direct contact with the emitter region, the body contact region, and the surface layer body region from below, being in direct contact with the rectangular trench, and having a p-type impurity concentration lower than that of the body contact region;
a drift region of n-type provided below the separation body region, separated from the emitter region by the separation body region, and being in direct contact with a lower end of the rectangular trench; and
a collector region of p-type provided below the drift region, separated from the separation body region by the drift region, and being in direct contact with the collector electrode,
the rectangular trench comprises a straight trench which constitutes one side of the rectangular trench,
the emitter region is in direct contact with the straight trench,
the surface layer body region is in direct contact with the straight trench in a range adjacent to the emitter region,
the body contact region is in direct contact with the emitter region from an opposite side to the straight trench,
the body contact region comprises a first part and a second part protruding toward the emitter region than the first part, and
a width of the emitter region between the second part and the straight trench is narrower than a width of the emitter region between the first part and the straight trench.

2. The insulated gate bipolar transistor of claim 1, wherein
the body contact region comprises a third part being in direct contact with the surface layer body region from an opposite side to the straight trench, and
a width of the surface layer body region between the third part and the straight trench is wider than the width of the emitter region between the second part and the straight trench.

3. The insulated gate bipolar transistor of claim 1, wherein the body contact region is not in direct contact with the straight trench.
